(19) United States
(12) Patent Application Publication
(10) Pub. No.: US 2012/0320508 A1
(43) Pub. Date: Dec. 20, 2012

(54) DISPLAY APPARATUS FOR A PASSENGER CABIN OF AN AIRCRAFT OR SPACECRAFT

(75) Inventors: CHRISTIAN RIEDEL, Bliedersdorf (DE); STEFAN MAHN, Buxtehude (DE); WOLFGANG FISCHER, Jork (DE)

(73) Assignee: AIRBUS OPERATIONS GMBH, Hamburg (DE)

(21) Appl. No.: 13/491,265

(22) Filed: Jun. 7, 2012

Related U.S. Application Data
(60) Provisional application No. 61/495,489, filed on Jun. 10, 2011.

(30) Foreign Application Priority Data
Jun. 10, 2011 (DE) 10 2011 077 344.4

(51) Int. Cl. H05K 7/00

(52) U.S. Cl. 361/679.01

(57) ABSTRACT

A display apparatus for a passenger cabin of an aircraft or spacecraft, said display apparatus comprising a display device, which is arranged at a predetermined display device inclination angle to a supply duct of the passenger cabin, wherein the display device is configured in such a way that a virtual image plane of the display device has a predetermined virtual image plane inclination angle to the supply duct, said virtual image plane inclination angle differing from the display device inclination angle. A passenger cabin for an aircraft or spacecraft comprising a display apparatus of this type, and an aircraft or spacecraft comprising a display apparatus of this type or comprising a passenger cabin of this type.

### CROSS-REFERENCE TO RELATED APPLICATIONS

This application claims the benefit of and priority to U.S. Provisional Application No. 61/495,489, filed Jun. 10, 2011 and German Patent Application No. 10 2011 077 344.4, filed Jun. 10, 2011, the entire disclosures of which are herein incorporated by reference.

### FIELD OF THE INVENTION

The present invention relates to a display apparatus for a passenger cabin of an aircraft or spacecraft, a passenger cabin for an aircraft or spacecraft comprising a display apparatus of this type, and an aircraft or spacecraft comprising a display apparatus of this type or comprising a passenger cabin of this type.

Although applicable to any aircraft or spacecraft, the present invention will be explained in greater detail by way of example with reference to an aeroplane.

In aircraft construction, hinged display apparatus (“retractable displays”) are often used in what are known as “in-flight entertainment (IFE) systems”. Hinged display apparatus of this type are mounted for example in an overhead region of a passenger cabin. To view information presented by the display apparatus, the crew folds open the display apparatus centrally. An inclination angle of the display apparatus suitable for the passenger is pre-set in a complex manner in accordance with the seating layout. The inclination angle is preferably greater than 90°. A hinged display apparatus of this type is described for example in DE 11 2008 001 451 T5.

The applicant is aware, in-house, of the problem that these hinged display apparatus are technically complex and susceptible to failure. If the hinge mechanism were omitted, this could thus save costs and weight as well as increase reliability considerably. However, fixed display apparatus mounted at an inclination angle comparable to the inclination angle of the folded-out hinged display apparatus are not possible for safety reasons. Conventional hinged display apparatus have to be folded in during the boarding, deboarding, and taxiing procedures of the aircraft, since an overview of the cabin has to be ensured and since the passengers could injure themselves on the folded-out display apparatus. A fixed display apparatus would therefore represent a significant safety risk. In addition, fixed display apparatus, which protrude too far from the supply duct arranged in the overhead region, are very unfavourable from an aesthetic point of view

### SUMMARY OF THE INVENTION

The object of the present invention is therefore to create a display apparatus which overcomes the aforementioned drawbacks.

Accordingly, a display apparatus for a passenger cabin of an aircraft or spacecraft is provided, comprising a display device, which is arranged at a predetermined display device inclination angle to a supply duct of the passenger cabin, wherein the display device is configured in such a way that a virtual image plane of the display device has a predetermined virtual image plane inclination angle to the supply duct, said virtual image plane inclination angle differing from the display device inclination angle.

The underlying concept of the present invention lies in the provision of a display apparatus in which the display device is arranged at a predetermined display device inclination angle, wherein information to be provided by apparatus of the display device is inclined towards the passengers in a virtual image plane. It is thus possible to dispense entirely with the capacity to fold in the display device and, at the same time, to ensure the maximum comfort for the passengers when viewing the information.

Advantageous configurations and improvements of the apparatus and of the passenger cabin can be found in the dependent claims.

In accordance with a preferred embodiment of the display apparatus, the display device is configured as an autostereoscopic multi-view 3D display. For example, the autostereoscopic multi-view 3D display has a lens matrix to provide two pieces of spatially offset image information. Prefabricated purchased parts can advantageously be used, thus making it possible to produce the display apparatus in a cost effective manner.

In accordance with a preferred embodiment of the display apparatus, the display apparatus has an inclination angle adjustment device to adjust the display device inclination angle. Rapid and simple adaptability of the display device inclination angle is hereby ensured, thus increasing operator comfort during operation of the display apparatus. Furthermore, this enables mechanical adaptation of the predetermined display device inclination angle, in addition to the adaptation of the predetermined virtual image plane inclination angle.

In accordance with a further preferred embodiment of the display apparatus, the virtual image plane inclination angle is greater than the predetermined display device inclination angle, whereby the virtual image plane is inclined towards the passengers in an optimal manner. This increases passenger comfort.

In accordance with a yet further preferred embodiment of the display apparatus, the display device is integrated, at least over portions, in a cover panel of the supply duct. This ensures particularly simple and rapid assembly of the display apparatus, thus increasing the possible fields of use thereof.

In accordance with a preferred configuration of the display apparatus, a width of the display device is greater than a width of the supply duct. The use of display devices having an excess width is thus possible. This increases the passengers' viewing comfort.

In accordance with a preferred embodiment of the passenger cabin, the display apparatus is arranged, at least over portions, in a supply duct of the passenger cabin. The space available in the passenger cabin for the passengers is increased hereby, thus increasing passenger comfort.

The invention will be explained in greater detail hereinafter on the basis of embodiments with reference to the accompanying schematic figures of the drawing.

### BRIEF DESCRIPTION OF THE DRAWINGS

In the schematic figures:

FIG. 1 is a perspective view of a preferred embodiment of a display apparatus for a passenger cabin of an aircraft or spacecraft;

FIG. 2 is a sectional view through a passenger cabin of an aircraft or spacecraft;

FIG. 3 is a front view of the preferred embodiment of the display device according to FIG. 1;

FIG. 4 is a perspective view of a further preferred embodiment of a display apparatus for a passenger cabin of an aircraft or spacecraft;

FIG. 5 is a front view of the preferred embodiment of the display device according to FIG. 4;

FIG. 6 is a perspective view of a yet further preferred embodiment of a display apparatus for a passenger cabin of an aircraft or spacecraft;

FIG. 7 is a sectional view of a configuration of the preferred embodiment of the display apparatus according to FIG. 6;

FIG. 8 is a sectional view of a configuration of the preferred embodiment of the display apparatus according to FIG. 6; and

FIG. 9 is a perspective view of a yet further preferred embodiment of a display apparatus for a passenger cabin of an aircraft or spacecraft.

### DESCRIPTION OF EXEMPLARY EMBODIMENTS

In the figures, like reference signs denote like or functionally like components, unless specified otherwise.

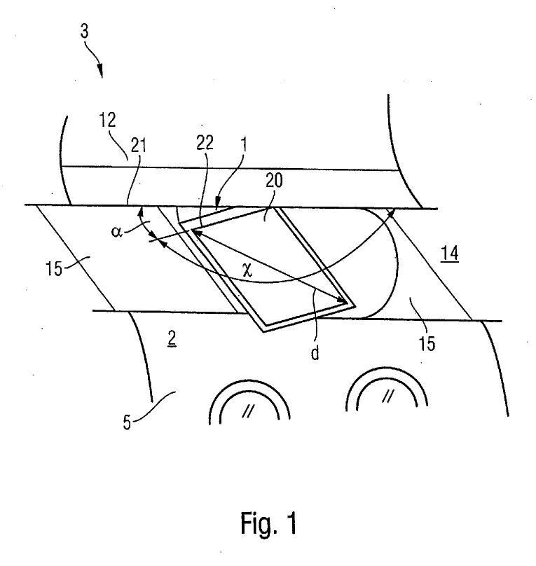

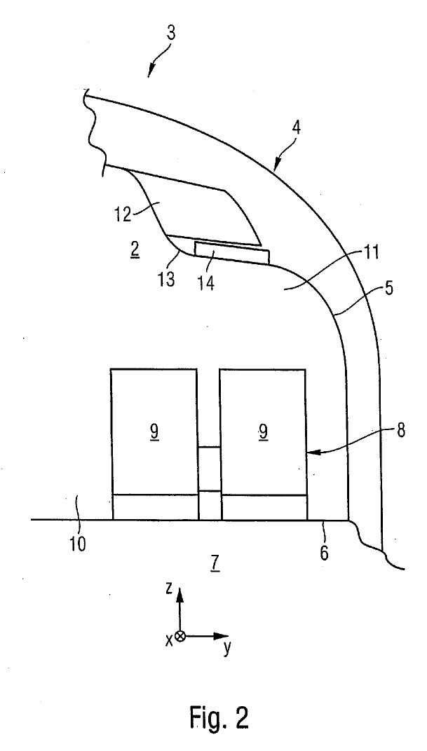

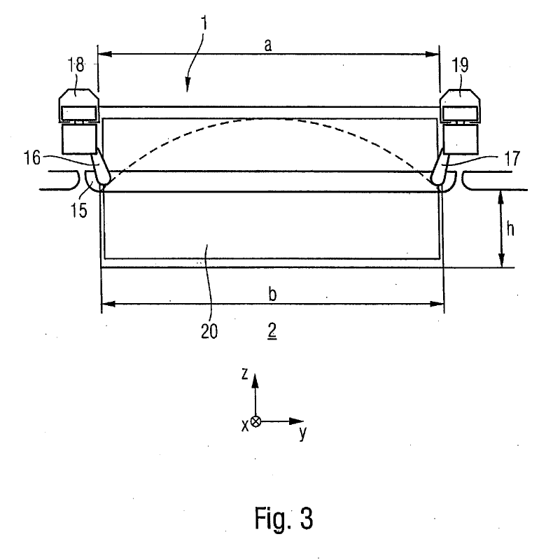

FIGS. 1 to 3, to which reference is made simultaneously hereinafter, illustrate a preferred embodiment of a display apparatus 1 for a passenger cabin 2 of an aircraft or spacecraft 3. The display apparatus 1 is preferably a component of what is known as an “in-flight entertainment system” (IFE system) of the aircraft or spacecraft 3. The IFE system may have a multiplicity of display apparatus 1. However, reference will be made hereinafter to just one display apparatus 1. In particular, the aircraft or spacecraft 3 has a fuselage 4, which for example is cylindrical or oval-cylindrical. An inner wall 5 of the fuselage 4 preferably forms a side wall 5 of the passenger cabin 2. A coordinate system illustrates an x-direction or longitudinal direction, a y-direction or transverse direction, and a z-direction or vertical direction of the fuselage 4 or of the aircraft or spacecraft 3. The passenger cabin 2 is separated approximately horizontally from a hold region 7 of the aircraft or spacecraft 3 by apparatus of a floor 6. The floor 6 extends preferably in a planar manner in the x-direction and in the y-direction. A plurality of rows of seats, spaced from one another in the x-direction, is preferably arranged on the floor 6. For example, a row of seats 8, in particular a right-hand row of seats 8, with two passenger seats 9 is provided in FIG. 2. The number of seats per row is arbitrary. An aisle 10 is provided between the right-hand row of seats 8 and a further row of seats (not illustrated), for example a middle or left-hand row of seats. A plurality of aisles may extend in the x-direction parallel to one another in the passenger cabin 2.

A storage or stowage device 12, known as a “hatrack” 12, is provided in an overhead region 11 of the row of seats 8. For example, the hatrack 12 is used for stowage of the passengers' hand luggage. The hatrack 12 preferably has a multiplicity of individual compartments, each comprising doors hinged so as to fold out into the passenger cabin 2. A supply duct 14 is provided on an underside 13 of the hatrack 12. For example, electrical and/or data lines are arranged in the supply duct 14. The supply duct 14 extends approximately in the x-direction. The supply duct 14 is preferably arranged substantially parallel to a plane spanned by the x-direction and y-direction. Alternatively to that illustrated in FIG. 2, the supply duct 14 can be arranged inclined towards the passenger cabin 2 or the aisle 10. The supply duct 14 is preferably covered towards the passenger cabin by apparatus of cover panels 15, in such a way that it is not visible. The cover panels 15 are preferably screwed to and/or snapped onto the supply duct 14. For example, the cover panels 15 are each mounted on longitudinal supports 18, 19 of the supply duct 14 by apparatus of fixing elements 16, 17, said longitudinal supports extending in particular in the x-direction. The supply duct 14 preferably has a width a. The width a of the supply duct may be predefined as standard.

In particular, the display apparatus 1 has a display device 20, in particular an overhead display 20. The display device 20 preferably has a liquid crystal display screen (LCD screen) or the like. The display device 20 is preferably mounted on a predetermined portion of the passenger cabin 2, for example on the supply duct 14 or at least over portions in the supply duct 14. Alternatively, the display device 20 can be mounted on any portion of the passenger cabin 2, in particular on a portion which is visible to the passengers. The display apparatus 1 also preferably comprises one of the cover panels 15, in which the display device 20 can be incorporated. For example, a housing of the display device 20 is integrated, at least over portions, in the corresponding cover panel 15. In particular, the display device 20 is mounted at a predetermined, in particular fixed, display device inclination angle a, in particular to the supply duct 14 of the passenger cabin 2. The predetermined display device inclination angle a is spanned in particular by a side edge 21, extending approximately in the longitudinal direction x of the aircraft and spacecraft 3, of the supply duct 14 and by a side edge 22 of a screen of the display device 20. Hereinafter, the screen of the display device 20 is understood to mean the component of the display device on which the information to be presented is shown to a viewer. For example, the screen may be a glass panel or plastics material panel. An angle extending the display device inclination angle α to 180° is referred to as the “aperture angle” χ of the display device 20. The aperture angle χ is preferably greater than an aperture angle of a conventional hinged display device (a “retractable display”). The display device 20, in particular the screen thereof, is preferably inclined towards passengers sitting in the row of seats 8. The display device inclination angle a is preferably configured as an acute angle. In a preferred embodiment of the display apparatus 1, the predetermined display device inclination angle a is set in a fixed manner, that is to say it is not adjustable.

The display device 20 preferably has a width b adapted to the width a of the supply duct 14, said width b in particular corresponding to the width a. For example, the display device 20 has a screen diagonal d of 10 inches. The width a of the supply duct 14 can be configured in such a way that the display device 20 with the screen diagonal d of 10 inches can be received, at least over portions, in the supply duct 14. The display device 20 is preferably arranged, at least over portions, in the supply duct 14. In particular, the display device 20 protrudes beyond the corresponding cover panel 15 of the supply duct 14, that is to say into the passenger cabin 2, merely by a height h. In particular, the height h is much shorter than in a conventional retractable display. Due to the short height h of the display device 20 protruding into the passenger cabin, the risk of injury to the passengers during boarding, deboarding and taxiing procedures is ruled out and an overview of the passenger cabin 2 is always ensured.

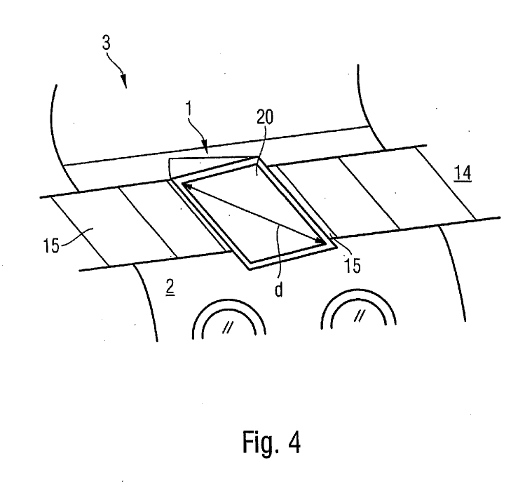

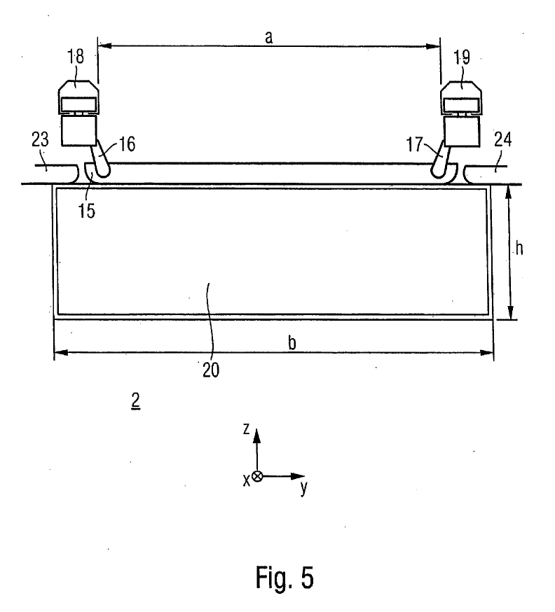

FIGS. 4 and 5 illustrate a preferred modification of the display apparatus 1 according to FIGS. 1 to 3. This modification of the display apparatus 1 is applied in particular with use of display devices 20 having a screen diagonal d of greater than or equal to 10 inches. The display device 20 in particular has a width b which is greater than the width a of the supply duct 14. The display apparatus 1 according to FIGS. 4 and 5 differs from the display apparatus 1 according to FIGS. 1 to 3 merely in that the display device 20 has a greater width b than the width a of the supply duct 14. For example, the standard width a of the supply duct 14 is configured in such a way that display devices 20 having a screen diagonal d of 10 inches can be mounted in the supply duct 14. However, due to the greater screen diagonal d of 12 inches, the width b of the display device 20 in accordance with the development according to FIGS. 4 and 5 is greater than the width a of the supply duct 14. In particular it is hereby possible to provide image information and/or video information to the passengers in a larger format, thus increasing passenger comfort. The display device 20 preferably protrudes on both sides beyond the supply duct 14 and, for example, rests on further panels 23, 24 of the side wall 5, said panels being mounted in the overhead region 11 beside the supply duct 20.

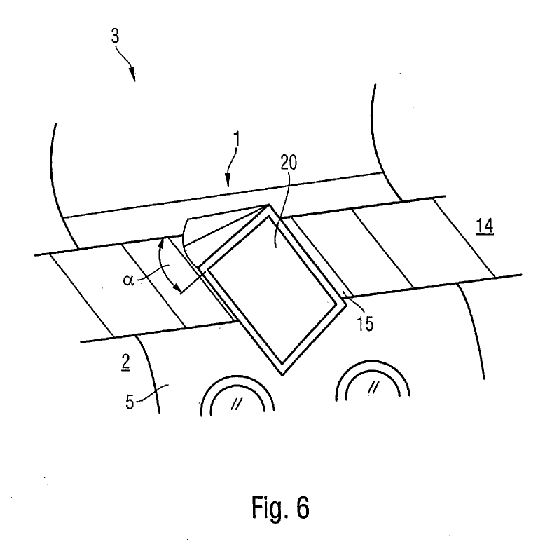

FIGS. 6 to 8 illustrate further preferred embodiments of the display apparatus 1. In these embodiments of the display 1 according to FIGS. 6 to 8, the predetermined display device inclination angle a is configured in particular so as to be mechanically adjustable. The display device 20 can thus be inclined towards or away from the passenger within a predetermined angular range. In particular, the display apparatus 1 may have a mechanical inclination angle adjustment device to adjust the display device inclination angle α.

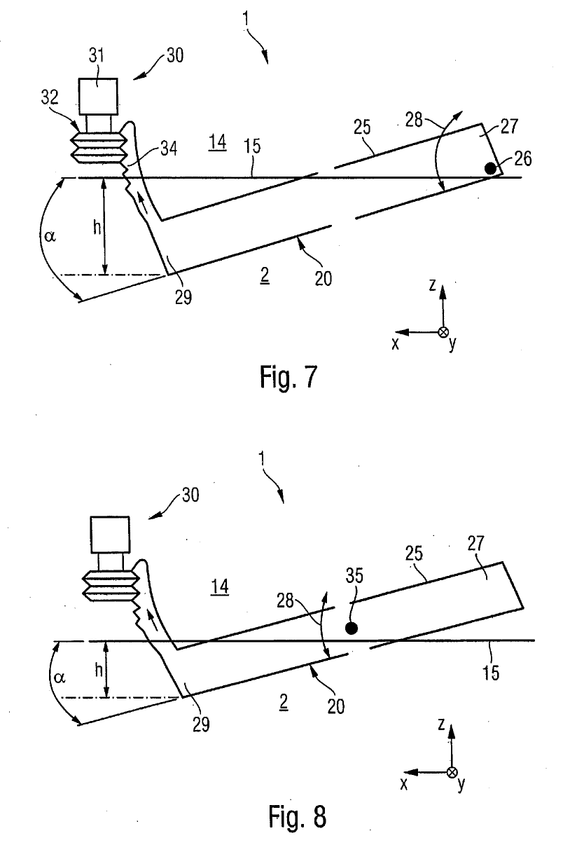

In a preferred configuration of the display apparatus 1 according to FIG. 7, the display device 20 or a housing 25 of the display device 20 has an axis of rotation 26, which is provided at an end portion 27 of the display device 20, said end portion facing away from the passenger cabin 2. The axis of rotation 26 is preferably arranged parallel to the transverse direction y. The end portion 27 is arranged in particular in the supply duct 14. The display device 20 can be pivoted about the axis of rotation 26, as illustrated by apparatus of the arrow 28. An inclination angle adjustment device 30 is arranged at a second end portion 29 of the display device 20, said second end portion facing away from the first end portion 27. The inclination angle adjustment device 30 is preferably mechanical. Alternatively for example, the inclination angle adjustment device 30 may be pneumatic or hydraulic. The second end portion 29 protrudes into the passenger cabin 2, in particular by a height h. The height h and the display device inclination angle α are mechanically adjustable by apparatus of the inclination angle adjustment device 30. For example, the inclination angle adjustment device 30 may have a drive device 31 and a transmission device 32. The drive device 31 is preferably configured as an electric machine 31 and is operatively connected by apparatus of the transmission device 32 to the display device 20 or to the housing 25 of the display device 20. For example, the transmission device 32 may have a pinion 33 operatively connected to the drive device 31, in particular a worm pinion 33, which engages in a corresponding rack 34 of the transmission device 32. The display device inclination angle a and the height h can be adjusted in a rapid and comfortable manner by apparatus of the inclination angle adjustment device 30.

FIG. 8 illustrates a further modification of the display apparatus 1, which differs from the configuration of the display apparatus 1 according to FIG. 7 merely in that an axis of rotation 35 arranged approximately centrally in the display device 20 or in the housing 25 of the display device 20 is provided instead of the axis of rotation 26 positioned at the first end portion 27. The axis of rotation 35 is preferably arranged parallel to the transverse direction y. The first end portion 27 is hereby arranged lower in the supply duct 14, thus resulting in a reduced height h of the display device 20 protruding into the passenger cabin compared to the configuration according to FIG. 7.

Since the display apparatus 1 according to the embodiments of FIGS. 1 to 8 is preferably arranged in the overhead region 11, information (understood hereinafter to mean an image and/or a video film for example) presented by apparatus of the display device 20 is perceived by the passengers to be compressed and/or distorted in a trapezoid manner, depending on the seat position. For virtual image adaptation, the display device 20 is preferably configured in such a way that it is possible to adapt the viewing angle. This adaptation of the viewing angle and rectification of the presented information is preferably achieved in a virtual manner by apparatus of a three-dimensional presentation.

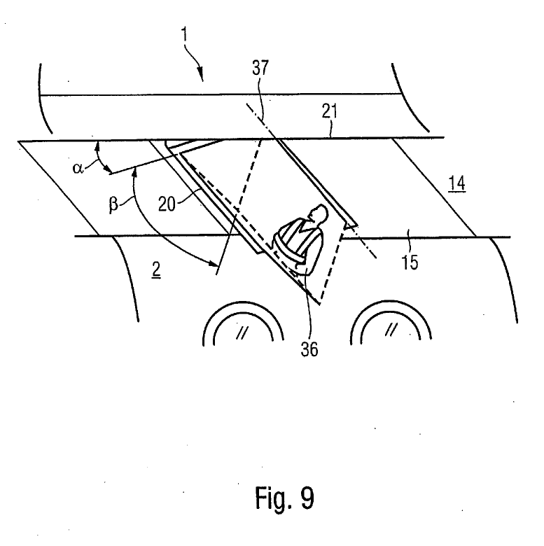

In particular, the display device 20, as illustrated in FIG. 9, is configured as what is known as an “autostereoscopic multi-view 3D display” 20, referred to hereinafter as a display 20. This preferably has a lens matrix, which is arranged in particular on a screen of the display 20. The screen forms a real image plane of the display 20. The display 20 can emit a piece of information received from a plurality of viewing angles in a plurality of separate viewing directions by apparatus of the lens matrix. If two of these spatially offset images individually impinge the left and right eye of a viewer, a three-dimensional impression is provided to the viewer. In the present case, a 2D video signal is preferably adapted by apparatus of 3D video signal processing so as to achieve virtual inclination and rectification of the information presented. The information presented is thus inclined towards the passenger over a virtual image plane 36. The virtual image plane 36 preferably differs from the real image plane of the display 20. In particular, the virtual image plane 36 of the display 20 has a predetermined virtual image plane inclination angle β, preferably differing from the predetermined display device inclination angle α. The predetermined virtual image plane inclination angle β is spanned in particular between the screen of the display device 20 and the virtual image plane 36. The predetermined virtual image plane inclination angle β and the predetermined, in particular mechanically adjustable, display device inclination angle α together give an overall inclination angle of the display apparatus 1. The virtual image plane 36 is preferably pivotable relative to the screen of the display 20 about a virtual axis of rotation 37. The virtual axis of rotation 37 is preferably arranged on a surface of the supply duct 14, that is to say on the cover panel 15. In particular, the virtual axis of rotation 37 corresponds to a front edge of the screen of the display 20. The virtual axis of rotation 37 is preferably arranged parallel to the transverse direction y. The predetermined image plane inclination angle β is preferably greater than the predetermined display device inclination angle α. Alternatively, the predetermined image plane inclination angle β is less than or equal to the predetermined display device inclination angle α. The predetermined image plane inclination angle β is preferably configured in such a way that information presented by apparatus of the display 20 is perceived by a passenger in an undistorted manner. The virtual image plane 36 appears visually to come out of the display 20. The information presented is rectified so that there is no trapeze shape, but for example the side edges of a 2D video image extend parallel to one another. The predetermined image plane inclination angle β is preferably adjustable. A further adjustment possibility of the display apparatus 1 or of the image or video presented is provided by the use of the inclination angle adjustment device 30 according to FIG. 7 or 8. In particular, the mechanical adjustability of the display device inclination angle a enables an additional adaptation and optimisation of the passengers' viewing direction or viewing angle to the information presented by the display apparatus 1.

In an alternative configuration of the display apparatus 1, a virtual axis of rotation of the virtual image plane 36 is located approximately in the centre of the information to be presented. In this alternative configuration, the passengers perceive part of the presented image in a virtual manner in the depth of the supply duct 14. In particular, this makes it possible to incline the presented information more steeply and enables improved image sharpness, since a maximum distance of the virtual image plane 36 from the display surface is shorter.

The display 20 is preferably configured in such a way that it provides a multiplicity of virtual image planes. Image information or video information can thus be provided simultaneously in an undistorted and/or uncompressed manner to a plurality of passengers sitting in different seats 9. With the configuration of the display apparatus 1 in such a way that the display device inclination angle α is set in a fixed manner and/or the necessary rectification is constant, a corresponding video material to be presented by the display 20 can be produced in advance for example by apparatus of processing software. Should it be necessary to adapt the video presentation during operation of the display 20, for example with adjustment of the display device inclination angle a, the corresponding signal processing may occur in real time, however, via accordingly configured processors of the IFE system. Furthermore, 3D video material can be presented in a rectified manner, adapted to the viewing angle, by the display apparatus 1.

The stated materials, figures, and dimensions are to be understood as being exemplary and are used merely for explanation of the embodiments and developments of the present invention.

Of course, application of the invention in other fields, in particular in vehicle construction and shipbuilding, is also conceivable. Application in the entertainment industry, in particular in the home-entertainment sector, is also possible.

### LIST OF REFERENCE NUMERALS

1 display apparatus
2 passenger cabin
3 aircraft or spacecraft
4 fuselage
5 side wall
6 floor
7 hold region
8 row of seats
9 seat
10 aisle
11 overhead region
12 storage device
13 underside
14 supply duct
15 cover panel
16 fixing element
17 fixing element
18 longitudinal support
19 longitudinal support
20 display device
21 side edge
22 side edge
23 panel
24 panel
25 housing
26 axis of rotation
27 end portion
28 arrow
29 end portion
30 inclination angle adjustment device
31 drive device
32 transmission device
33 pinion
34 rack
35 axis of rotation
36 virtual image plane
37 virtual axis of rotation
a width
b width
d screen diagonal
h height
α display device inclination angle
β image plane inclination angle
χ aperture angle

1. A display apparatus for a passenger cabin of an aircraft or spacecraft, said display apparatus comprising a display device, which is arranged at a predetermined display device inclination angle to a supply duct of the passenger cabin, wherein the display device is configured in such a way that a virtual image plane of the display device has a predetermined virtual image plane inclination angle to the supply duct, said virtual image plane inclination angle differing from the display device inclination angle.

2. The display apparatus according to claim 1, wherein the display device is configured as an autostereoscopic multi-view 3D display.

3. The display apparatus according to claim 1, wherein the display apparatus has an inclination angle adjustment device to adjust the display device inclination angle.

4. The display apparatus according to claim 1, wherein the virtual image plane inclination angle is greater than the predetermined display device inclination angle.

5. The display apparatus according to claim 1, wherein the display device is integrated, at least over portions, in a cover panel of the supply duct.

6. The display apparatus according to claim 1, wherein a width of the display device is greater than a width of the supply duct.

7. A passenger cabin for an aircraft or spacecraft comprising a display apparatus according to claim 1.

8. A passenger cabin according to claim 7, wherein the display apparatus is arranged, at least over portions, in a supply duct of the passenger cabin.

9. An aircraft or spacecraft comprising a display apparatus according to claim 1.

10. An aircraft or spacecraft comprising a passenger cabin according to claim 7.
